(19) United States
(12) Patent Application Publication
(10) Pub. No.: US 2019/0354008 A1
(43) Pub. Date: Nov. 21, 2019

(54) STAMP FOR NANO IMPRINTING PROCESS AND METHOD OF FABRICATING THE STAMP

(71) Applicant: Samsung Display Co., Ltd., Yongin-Si (KR)

(72) Inventors: Junggun NAM, Suwon-si (KR); Taewoo KIM, Seoul (KR); Eunjung KIM, Suwon-si (KR); Seongsoon CHO, Suwon-si (KR)

(21) Appl. No.: 16/409,973

(22) Filed: May 13, 2019

(30) Foreign Application Priority Data
May 15, 2018 (KR) 10-2018-0055249

(51) Int. Cl. G03F 7/00

(52) U.S. Cl. CPC G03F 7/0002; B82Y 10/00

(57) ABSTRACT

A nano-imprinting stamp may include a base substrate, an imprint pattern provided on the base substrate, and an alignment pattern provided on the base substrate adjacent to the imprint pattern, the alignment pattern, each of which has a different shape from the imprint pattern. The base substrate may include a groove region formed between the imprint pattern and the alignment pattern in which a top surface of the imprint pattern being lower than a bottom surface of the alignment pattern.

### CROSS-REFERENCE TO RELATED APPLICATIONS

This U.S. non-provisional patent application claims priority under 35 U.S.C. § 119 to Korean Patent Application No. 10-2018-0055249, filed on May 15, 2018, in the Korean Intellectual Property Office, the entire contents of which are hereby incorporated by reference.

### BACKGROUND OF THE INVENTIVE CONCEPT

The present disclosure relates to a stamp for a nano imprinting process and a method of fabricating the stamp, and in particular, to a nano-imprinting stamp with improved uniformity and a method of fabricating the same.

In general, a nano imprint technology is used to form a nano-scale fine pattern. For example, the nano imprint technology is used to form fine patterns in a display panel or a semiconductor chip or is used to etch a plurality of stacked thin films. In the thin-film etching method using the nano imprint technology, a thin film is pressed by a stamp with patterns, and in this case, patterns corresponding to those in the stamp are formed in the thin film. The nano imprint technology simplifies a thin-film patterning process. Thus, the thin-film patterning process may be performed with high productivity and low cost.

A nano-pattern for a large area device is formed by performing an imprinting step, in which a stamp is used, several times. In this case, there is a difficulty in preventing misalignment between nano-size fine patterns and misalignment between positions of stamps to be used in the imprinting steps.

### SUMMARY

An embodiment of the inventive concept provides a nano-imprinting stamp with improved uniformity. Furthermore, an embodiment of the inventive concept provides a method of fabricating a nano-imprinting stamp.

According to an embodiment of the inventive concept, a nano-imprinting stamp may include a base substrate, an imprint pattern provided on the base substrate, and an alignment pattern provided on the base substrate adjacent to the imprint pattern, the alignment pattern having a different shape from the imprint pattern. The base substrate may include a groove region formed between the imprint pattern and the alignment pattern in which a top surface of the imprint pattern being lower than a bottom surface of the alignment pattern.

In an embodiment, the base substrate may include an active region, which has a rectangular planar shape, and a peripheral region, which is disposed adjacent to an edge of the active region. The imprint pattern may be provided on the active region, and the groove region and the alignment pattern may be provided on the peripheral region.

In an embodiment, the nano-imprinting stamp may further include an additional pattern provided between the groove region and the imprint pattern. The additional pattern may have substantially a same shape as the imprint pattern.

In an embodiment, when measure in a specific direction, a sectional width of the imprint pattern may range from 30 nm to 50 nm, and a sectional width of the alignment pattern may range from 1 μm to 100 μm.

In an embodiment, the imprint pattern may include a plurality of nano-patterns, which extend in a predetermined direction and are spaced apart from each other in a direction crossing the predetermined direction. The nano-patterns may be provided to have a pitch ranging from 90 nm to 100 nm.

In an embodiment, the imprint pattern may have a trapezoidal shape, when viewed in a sectional view.

In an embodiment, the base substrate may have a circular shape, when viewed in a plan view.

According to an embodiment of the inventive concept, a nano-imprinting stamp may include a base substrate including an active region and a peripheral region adjacent to the active region, the base substrate including a groove region which is provided in the peripheral region and is recessed from a top surface of the base substrate, an imprint pattern provided on the active region, an alignment pattern spaced apart from the imprint pattern, the alignment pattern, and an additional pattern disposed on both of the active region and the peripheral region and provided between the imprint pattern and the alignment pattern. The additional pattern may have substantially a same shape as the imprint pattern.

In an embodiment, the groove region may be provided between the additional pattern and the alignment pattern.

In an embodiment, the alignment pattern have a mesh-shaped structure in which a plurality of openings are formed, may have a stripe structure including a plurality of line patterns and a plurality of openings interposed between the line patterns or may have a cross-like shape when viewed in a plan view.

In an embodiment, a thickness of the imprint pattern may be substantially equal to a depth of the groove region.

In an embodiment, the first sub-pattern may have a mesh-shaped structure in which a plurality of openings are formed.

In an embodiment, the first sub-pattern may have a stripe structure including a plurality of line patterns and a plurality of openings interposed between the line patterns.

According to an embodiment of the inventive concept, a method of fabricating a nano-imprinting stamp may include providing a preliminary substrate including a base substrate and an etch layer disposed on the base substrate to fully cover the base substrate; forming a blocking mask to cover a portion of the etch layer overlapped with an active region and to expose a portion of the etch layer overlapped with an peripheral region; forming an alignment pattern by coating the preliminary substrate with a first masking layer and performing a first patterning process using a first mask; removing a portion of the base substrate which is exposed by the blocking mask and the alignment pattern to form a groove region; and forming an imprint pattern by coating the preliminary substrate with a second masking layer and performing a second patterning process using a second mask, the imprint pattern having a different shape from the alignment pattern, wherein the first mask is formed to expose a portion of the first masking layer overlapped with the peripheral region, and the second mask is formed to expose a portion of the second masking layer overlapped with the active region

In an embodiment, the first patterning process may further include hardening the exposed portion of the first masking layer, which is exposed by the first mask, to form a first photomask.

In an embodiment, the alignment pattern may be formed by etching a region of the etch layer exposed by the first photomask.

In an embodiment, the second patterning process may further include hardening the exposed portion of the second masking layer, which is exposed by the second mask, to form a second photomask.

In an embodiment, the imprint pattern may be formed by etching a region of the etch layer exposed by the second photomask.

In an embodiment, the first patterning process may include a plurality of first unit steps, each of which is performed to define a first unit region for the alignment pattern. The second patterning process may include a plurality of second unit steps, each of which is performed to define a second unit region for the imprint pattern. The peripheral region may be divided by a plurality of the first unit regions and the second unit region adjacent to the first unit region, and the active region may be divided by a plurality of the second unit regions.

In an embodiment, the method may further include an edge region overlapped with a portion of the peripheral region. One of the first unit steps may be performed on the edge region to form the imprint pattern on the edge region.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a nano-imprinting stamp according to an embodiment of the inventive concept.

FIGS. 2A and 2B are plan views each illustrating a region of a nano-imprinting stamp according to an embodiment of the inventive concept.

FIG. 3 is an enlarged view illustrating a region of a nano-imprinting stamp according to an embodiment of the inventive concept.

FIG. 4A is a sectional view taken along line I-I′ of FIG. 3.

FIG. 4B is an enlarged view of a region QQ′ of FIG. 4A.

FIG. 4C is an enlarged view illustrating a region of a nano-imprinting stamp according to an embodiment of the inventive concept.

FIGS. 5A, 5B and 5C are plan views each illustrating a nano-imprinting stamp according to an embodiment of the inventive concept.

FIGS. 6A, 6B, 6C, 6D, 6E, 6F, 6G, 6H, 6J, 6K and 6L are sectional views illustrating a method of fabricating a nano-imprinting stamp, according to an embodiment of the inventive concept.

FIG. 7 is a plan view illustrating a nano-imprinting stamp according to an embodiment of the inventive concept.

FIGS. 8A, 8B and 8C are plan views each illustrating a nano-imprinting stamp according to an embodiment of the inventive concept.

FIGS. 9A, 9B and 9C are plan views each illustrating a usage example of a nano-imprinting stamp according to an embodiment of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concept will now be described more fully with reference to the accompanying drawings, in which example embodiments are shown. Example embodiments of the inventive concept may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concept belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

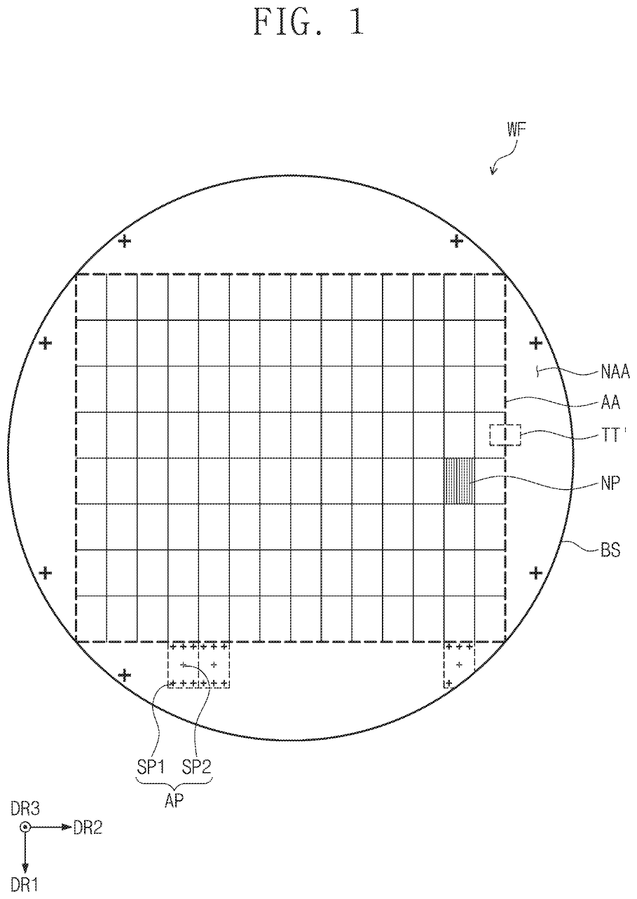

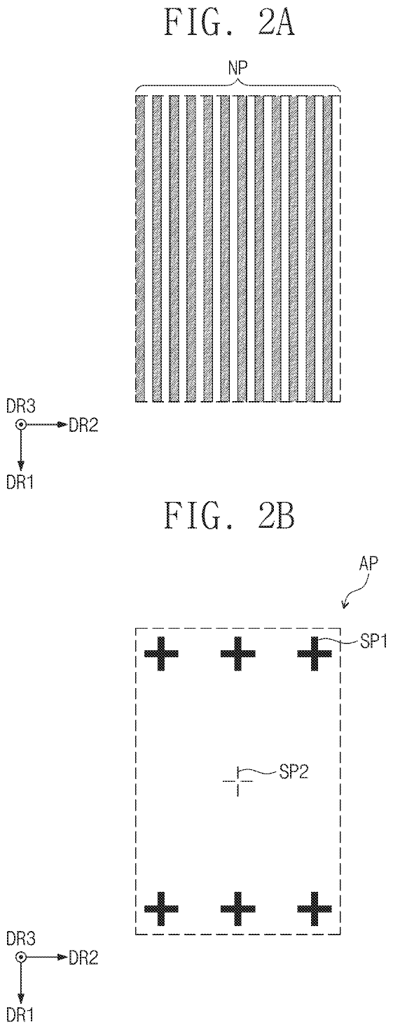

FIG. 1 is a plan view illustrating a nano-imprinting stamp according to an embodiment of the inventive concept. FIGS. 2A and 2B are plan views each illustrating a region of a nano-imprinting stamp according to an embodiment of the inventive concept. Hereinafter, a nano-imprinting stamp according to an embodiment of the inventive concept will be described with reference to FIGS. 1, 2A, and 2B.

Referring to FIG. 1, a nano-imprinting stamp WF may include an active region AA and a peripheral region NAA. The nano-imprinting stamp WF may include a base substrate BS, an alignment pattern AP, and an imprint pattern NP.

For example, when viewed in a plan view, the active region AA may have a rectangular shape whose sides are parallel to a first direction DR1 or a second direction DR2.

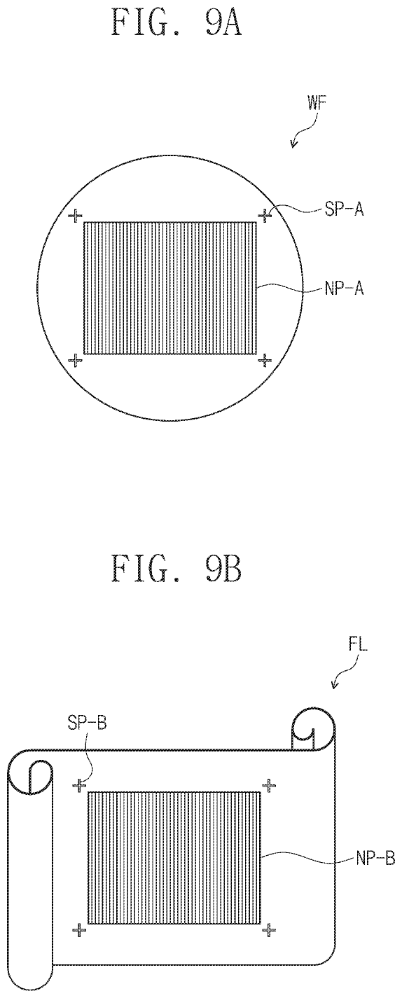

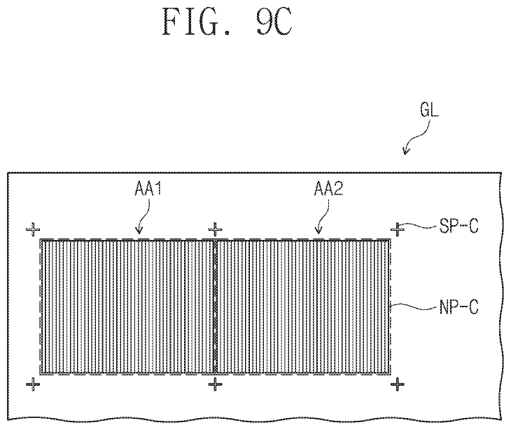

The peripheral region NAA may be located adjacent to the active region AA to surround the active region AA. In a process of transcribing or copying a shape of the imprint pattern NP on the active region AA onto a film substrate FL (e.g., see FIG. 9B), the nano-imprinting stamp WF may be used as a master substrate, and the active region AA may be used as a transcription region to be transcribed onto the film substrate FL. In an embodiment, the transcription process using the nano-imprinting stamp WF may be performed to form a polarizer constituting a display panel.

The imprint pattern NP may be provided on the active region AA. In the transcription process using the nano-imprinting stamp WF, it may be necessary to align a plurality of the active regions AA with each other. The alignment pattern AP may be provided on the peripheral region NAA and may be used for alignment between nano-patterns constituting the imprint pattern NP and for alignment between the active regions AA. Since a wafer is too large to be exposed by a single exposure step, a photolithography or patterning process to be described below may include a plurality of exposure steps. Each of rectangular regions (One of the solid line areas indicated by the square) depicted by solid line in the active region AA of FIG. 1 may correspond to a shot region, on which each of the single exposure step will be performed.

The base substrate BS may be a base layer supporting a plurality of patterns. Although the base substrate BS is illustrated to have a circular shape, the inventive concept is not limited thereto. For example, in an embodiment, the base substrate BS may be provided to have a polygonal shape.

Referring to FIG. 2A, the imprint pattern NP may include a plurality of nano-patterns which extend in the first direction DR1 and are spaced apart from each other in the second direction DR2 when viewed in a plan view.

Referring to FIG. 2B, at least one first sub-pattern SP1 may be used for the alignment between adjacent ones of the active regions in the transcription process using a nano imprint process. In an embodiment, a plurality of the first sub-patterns SP1 may be provided within the alignment pattern AP. For convenience in illustration, FIG. 1 illustrates an example in which the alignment pattern AP includes a plurality of first sub-patterns SP1 and one second sub-pattern SP2. In FIG. 2B, the first sub-patterns SP1, each of which has a cross-like shape (+), are arranged in two rows and three columns, but the inventive concept is not limited thereto. If the first sub-patterns SP1 are provided in a symmetric manner within the alignment pattern AP, shape and number of the first sub-patterns SP1 may be variously changed.

The second sub-pattern SP2 may be used to align a plurality of nano-patterns which are provided in adjacent shot regions with each other in a process of forming the imprint pattern NP. The second sub-pattern SP2 may be used when a plurality of nano-patterns are formed by a photolithography or patterning process. For example, the second sub-pattern SP2 may be used for precise alignment between nano-patterns which are respectively formed in two different shot regions located adjacent to each other in both of horizontal and vertical directions, and this may make it possible to prevent a distinct border between the nano-patterns from being formed. The first sub-pattern and the second sub-pattern SP1 and SP2 may be provided to have different shapes from each other, but the inventive concept is not limited thereto.

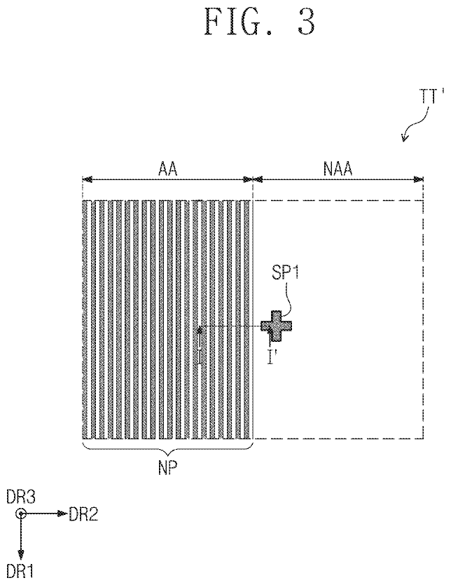

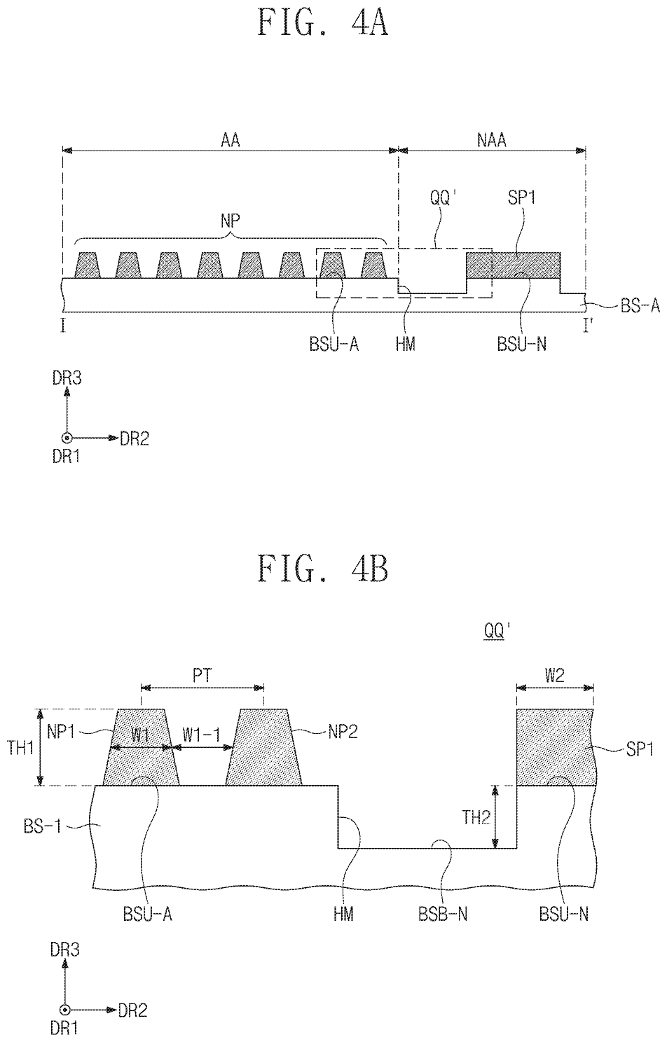

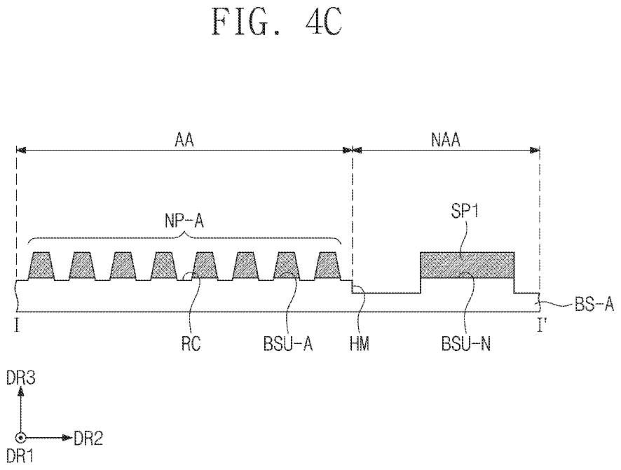

FIG. 3 is an enlarged view illustrating a region of a nano-imprinting stamp according to an embodiment of the inventive concept. FIG. 4A is a sectional view taken along line I-I′ of FIG. 3. FIG. 4B is an enlarged view of a region QQ′ of FIG. 4A. FIG. 4C is an enlarged view illustrating a region of a nano-imprinting stamp according to an embodiment of the inventive concept.

As shown in FIG. 3, in a region TT′, the imprint pattern NP may be provided to be spaced apart from the first sub-pattern SP1. For example, as shown in FIG. 4A, the imprint pattern NP may be provided on a first top surface BSU-A. Here, the first top surface BSU-A may be a portion of the top surface of the base substrate BS overlapped with the active region AA. The imprint pattern NP may include a plurality of nano-patterns which extend in the first direction DR1 and are arranged in the second direction DR2. Each of the nano-patterns may have a tapered shape, for example, a trapezoidal shape, when viewed in a sectional view.

The first sub-pattern SP1 may be provided on a second top surface BSU-N. Here, the second top surface BSU-N may be a portion of the top surface of the base substrate BS overlapped with the peripheral region NAA. Although not shown, the second sub-pattern SP2 may also be provided on the second top surface BSU-N. The first sub-pattern SP1 and the second sub-pattern SP2 may be spaced apart from the imprint pattern NP.

In an embodiment, the base substrate BS may further include a groove region HM. The groove region HM may be provided between the imprint pattern NP and the alignment pattern AP. The groove region HM may be provided in the peripheral region NAA. The groove region HM may be a gap region which is defined by a recessed portion of the second top surface BSU-N around the first and second sub-patterns SP1 and SP2. Thus, the first and second sub-patterns SP1 and SP2 may be provided on the second top surface BSU-N to be isolated from each other.

In an embodiment of the inventive concept, since the groove region HM, which is recessed relative to the top surface of the base substrate BS, is provided, it may be possible to more clearly distinguish the alignment pattern AP from the imprint pattern NP.

FIG. 4B illustrates an enlarged shape of the region QQ′ of FIG. 4A. FIG. 4B illustrates a first nano-pattern NP1 and a second nano-pattern NP2 which are adjacent to the groove region HM included in the imprint pattern NP.

A width W1, in the second direction DR2, of the first nano-pattern NP1 may range from 30 nm to 50 nm.

A pitch PT, in the second direction DR2, between the first and second nano-pattern NP1 and NP2 may range from 90 nm to 100 nm.

When measured from the first top surface BSU-A in a third direction DR3, a first thickness TH1 of the first nano-pattern NP1 may be about 100 nm.

In an embodiment, a second thickness TH2, in the third direction DR3, of the groove region HM may be a distance from a bottom surface BSB-U to the second top surface BSU-N. In an embodiment, the second thickness TH2 may be equal to the first thickness TH1. The second thickness TH2 may be larger than two times of the first thickness TH1.

When measured in the second direction DR2 and at a middle point of the first nano-pattern NP1, a width W1 of the first nano-pattern NP1 may be substantially equal to a distance W1-1 between the first and second nano-pattern NP1 and NP2 spaced apart from each other.

A second width W2, in the second direction DR2, of the first sub-pattern SP1 may range from 1 μm to 100 μm. When the second width W2 is less than 1 μm, there may be a difficulty in recognizing the first sub-pattern SP1 in a subsequent misalignment inspection process. By contrast, when the second width W2 is larger than 100 μm, the peripheral region NAA may have an unnecessarily large area, and this may lead to a reduction in area efficiency of the nano-imprinting stamp WF. The first width W1 may be smaller than the second width W2.

Referring to FIG. 4C, the top surface of the base substrate BS may have recessed regions RC which are formed between nano-patterns of an imprint pattern NP-A. When forming the imprint pattern NP, the recessed regions RC may be formed by an over-etching process.

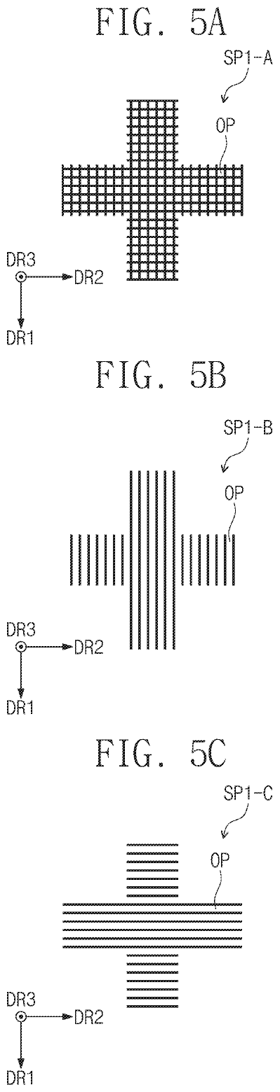

FIGS. 5A to 5C are plan views each illustrating a nano-imprinting stamp according to an embodiment of the inventive concept.

Referring to FIG. 5A, a first sub-pattern SP1-A may include a plurality of line patterns extending in two different directions. For example, the first sub-pattern SP1-A may be provided to have a mesh-shaped structure in which a plurality of openings OP are formed. Here, the openings OP may be formed by recessing at least of the first sub-pattern SP1-A in the third direction DR3. Although FIG. 5A illustrates an example in which the opening OP has a rectangular or square shape, the inventive concept is not limited thereto. For example, the shape of the opening OP may be variously changed, if the first sub-pattern SP1-A is formed to have a clearly recognizable shape.

As shown in FIG. 5B, a first sub-pattern SP1-B may include a plurality of line patterns which extend in the first direction DR1 and are spaced apart from each other in the second direction DR2. For example, the first sub-pattern SP-B may be provided to have a stripe structure including the line patterns and openings OP interposed therebetween. Here, the openings OP may be formed by recessing the first sub-pattern SP1-B in the third direction DR3.

As shown in FIG. 5C, a first sub-pattern SP1-C may include a plurality of line patterns, which extend in the second direction DR2 and are spaced apart from each other in the first direction DR1, unlike the structure shown in FIG. 5B.

The first sub-patterns according to the above embodiments of the inventive concept may be provided to have the opening OP which is recessed in the third direction DR3, and in this case, due to a difference in refractive index between the first sub-pattern SP1 and the air filling the opening OP, the first sub-patterns may be more clearly recognized.

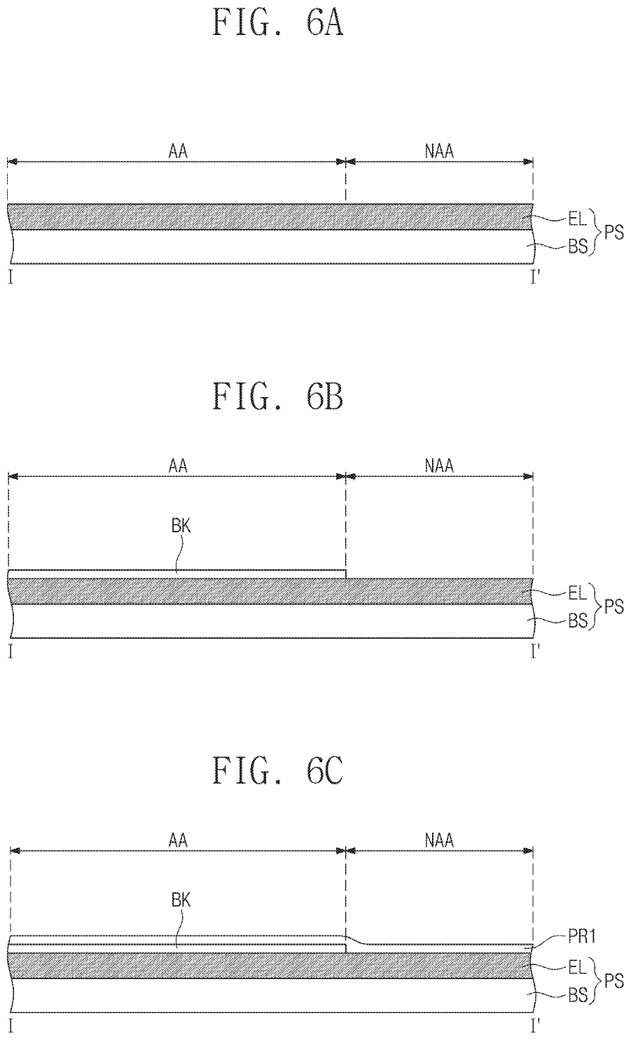

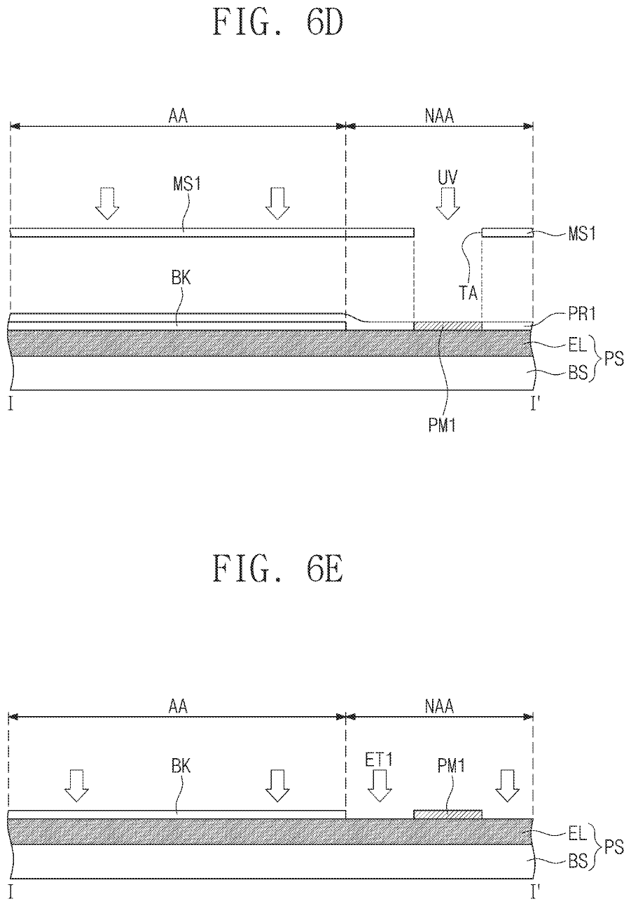

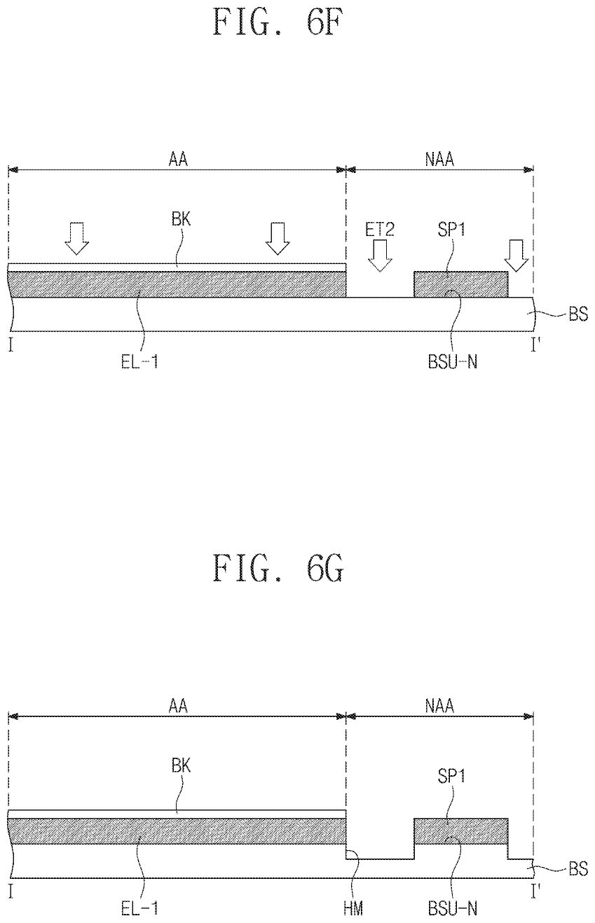

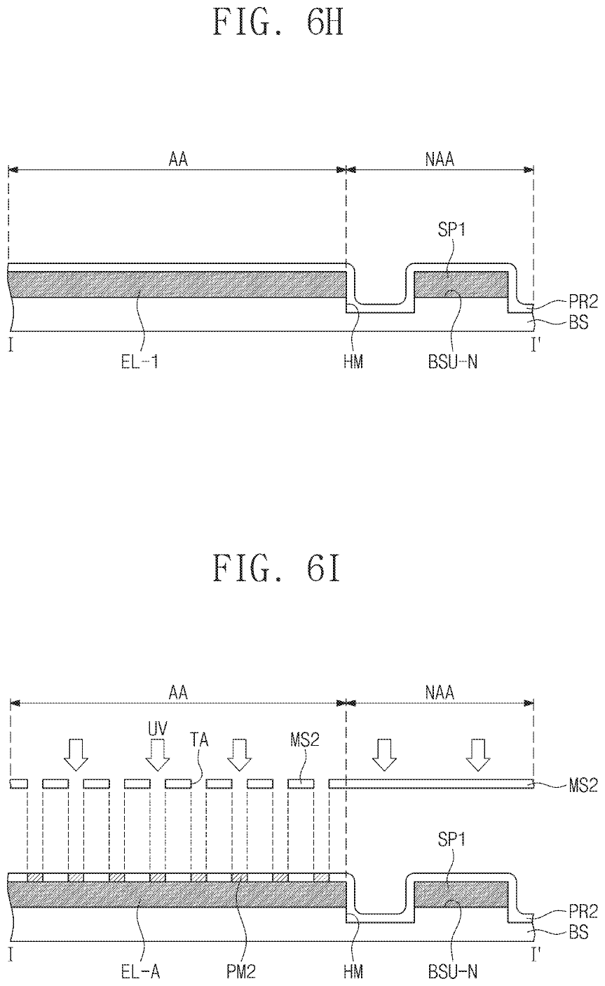

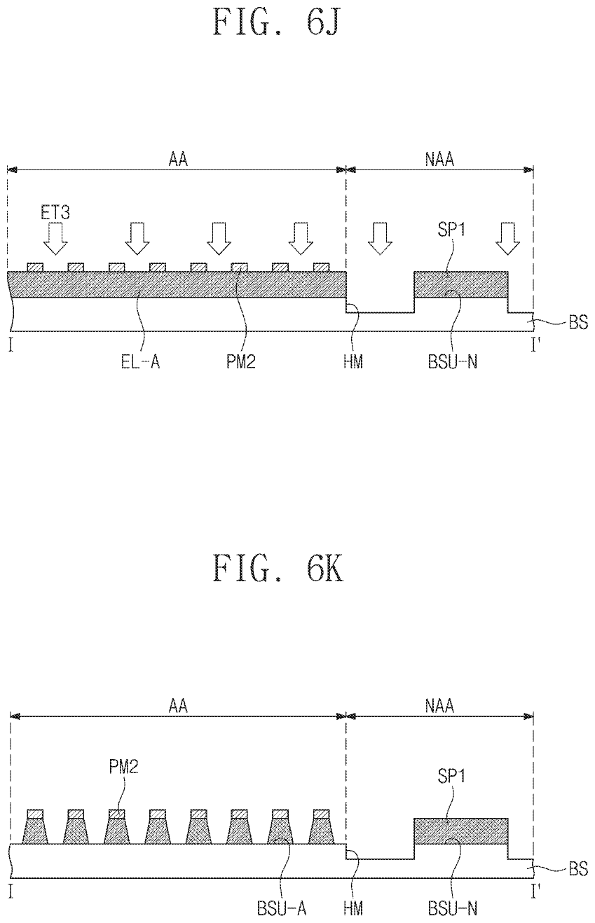

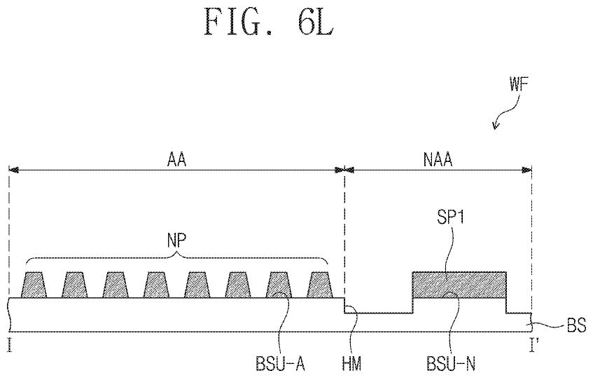

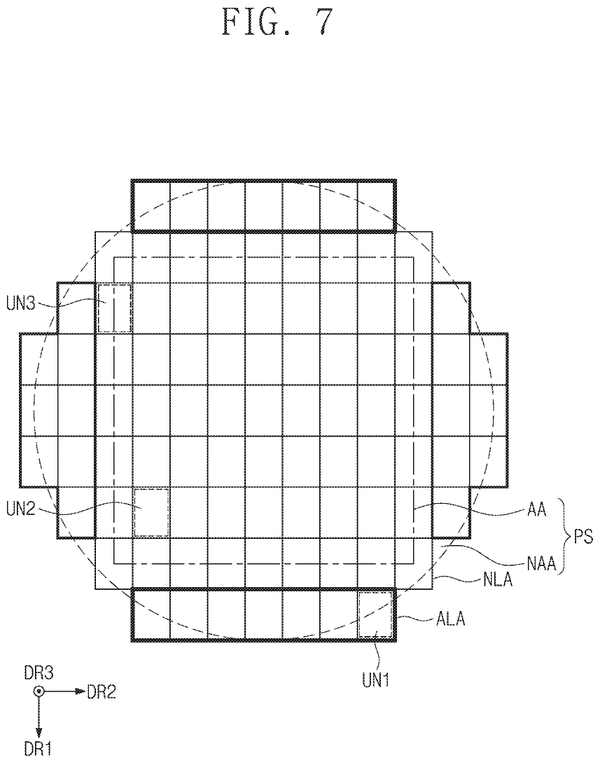

FIGS. 6A to 6L are sectional views illustrating a method of fabricating a nano-imprinting stamp, according to an embodiment of the inventive concept. FIGS. 6A to 6L exemplarily illustrate a method of fabricating the nano-imprinting stamp WF shown in FIGS. 1, 2A, 2B, 3, and 4A. Hereinafter, a method of fabricating a nano-imprinting stamp according to an embodiment of the inventive concept will be described in more detail with reference to FIGS. 6A to 6L.

As shown in FIG. 6A, a preliminary substrate PS including the base substrate BS coated with an etch layer EL may be provided. The base substrate BS may be formed of or include highly rigid polymer materials, quartz, or glass. The highly rigid polymer materials may include, for example, acrylate, urethane, or silicon-containing polymers. The etch layer EL may be formed of or include an inorganic material. The etch layer EL may be formed of or include, for example, silicon oxide or silicon nitride. The etch layer EL may be formed by depositing the inorganic material on the base substrate BS.

Thereafter, as shown in FIG. 6B, a blocking mask BK may be formed on a region of the preliminary substrate PS corresponding to the active region AA. The blocking mask BK may be formed to cover a portion of the etch layer EL overlapped with the active region AA and to expose another portion of the etch layer EL overlapped with a non-active region BAA. The blocking mask BK may be formed of or include at least one of light-blocking materials, but the inventive concept is not limited to a specific material for the blocking mask BK.

Thereafter, as shown in FIGS. 6C and 6D, a first masking layer PR1, for example a photo-resist layer, may be coated on the preliminary substrate PS. A first mask MS1 may be disposed on the first masking layer PR1. The first mask MS1 may include a transmission region TA. The transmission region TA may be overlapped with a portion of the first masking layer PR1 overlapped with the peripheral region NAA.

Light UV may be irradiated onto the first mask MS1 to harden a region of the first masking layer PR1 overlapped with the transmission region TA. The hardened region of the first masking layer PR1 may be used as a first photomask PM1. In an embodiment, the light UV may be ultraviolet light.

Next, as shown in FIGS. 6E to 6G, the first sub-pattern SP1 may be formed by, for example, etching the etch layer EL using a first etching gas ET1. The first photomask PM1 may be used as an etch mask defining a position and a shape of the first sub-pattern SP1. The first photomask PM1 may be formed by removing the first masking layer PR1, except for the hardened region, after the light irradiation step.

In an embodiment, the first sub-pattern SP1 may be formed by a dry etching process or a wet etching process. The first photomask PM1 may be formed to cover a portion of the etch layer EL overlapped with the peripheral region NAA and thereby to prevent from etching the etch layer EL disposed below the first photo mask PM1. On the active region AA, the blocking mask BK may be used to prevent the etch layer EL disposed below the blocking mask BK from being etched by the first etching gas ET1. Thus, the first etching gas ET1 may not etch the etch layer EL overlapped with the active region AA but may be used to etch a portion of the etch layer EL exposed by the first photomask PM1 and the blocking mask BK. As a result, the base substrate BS may be exposed around the first photomask PM1, and the first sub-pattern SP1 may be formed below the first photomask PM1. The first photomask PM1 may be removed by an ashing process.

Thereafter, a second etching gas ET2 may be used to partially etch the exposed portion of the base substrate BS. The second etching gas ET2 may be selected to allow the base substrate BS to have an etch rate higher than that of the etch layer EL. Thus, a portion of the base substrate BS not covered by the first sub-pattern SP1 in the peripheral region NAA may be removed to form the groove region HM.

Thereafter, as shown in FIG. 6H, the blocking mask BK may be removed from the preliminary substrate BS, and then, a second masking layer PR2 may be formed to conformally cover the structure, from which the blocking mask BK is removed. In an embodiment, the second masking layer PR2 may include a plurality of layers. For example, the second masking layer PR2 may include an anti-reflection layer (e.g., a bottom antireflective coating (BARC) layer) for preventing light UV from being reflected by the groove region HM in a subsequent irradiation process (e.g., see FIG. 6I). Furthermore, the second masking layer PR2 may include a layer, in which at least one of silicon oxynitride or silicon hydroxide is contained.

A second mask MS2 may be disposed on the second masking layer PR2. The second mask MS2 may be formed to have the transmission region TA. The transmission region TA may be overlapped with a region of the second masking layer PR2 overlapped with the active region AA. The second mask MS2 may be overlapped with the peripheral region NAA. Thus, the light UV, which is provided through the second mask MS2, may locally harden a portion of the second masking layer PR2 located on the active region AA.

The light UV may be irradiated onto the second mask MS2 and may harden a region of the second masking layer PR2 overlapped with the transmission region TA. The hardened region of the second masking layer PR2 may be used as a second photomask PM2.

Thereafter, as shown in FIGS. 6I to 6K, the imprint pattern NP may be formed by, for example, etching the etch layer EL exposed by the second photomask PM2 using a third etching gas ET3. The imprint pattern NP may be formed by using the second photomask PM2 as a etch mask. The second photomask PM2 may be formed by removing the second masking layer PR2, except for the hardened region, after the light irradiation step.

The second photomask PM2 may be formed to cover portions of the etch layer EL overlapped with the active region AA and thereby to prevent the covered portions of the etch layer EL from being exposed to the third etching gas ET3. Portions of the etch layer EL exposed by the second photomask PM2 may be removed by the third etching gas ET3. As a result, the imprint pattern NP may be formed on the base substrate BS, and in this case, a shape of the imprint pattern NP may be defined by a shape of the second photomask PM2.

Next, as shown in FIG. 6L, the second photomask PM2 may be removed by, for example, an ashing process. In the nano-imprinting stamp WF according to an embodiment of the inventive concept, the imprint pattern NP, the alignment pattern AP, and a groove region between the imprint pattern NP and the alignment pattern AP may be formed by a patterning or photolithography process.

Although not shown, the second sub-pattern SP2 and the first sub-pattern SP1 may be formed on the same layer, using the same process. Thus, the alignment pattern AP including the first sub-pattern and the second sub-pattern SP1 and SP2 may be formed by a single patterning process. Although the etching process is described to be performed using an etching gas, the inventive concept is not limited thereto. For example, the etching process may be performed using an etching solution.

In the process of fabricating the nano-imprinting stamp, the steps described with reference to FIGS. 6C to 6G will be defined as a first patterning process, the steps described with reference to FIGS. 6H to 6L will be defined as a second patterning process.

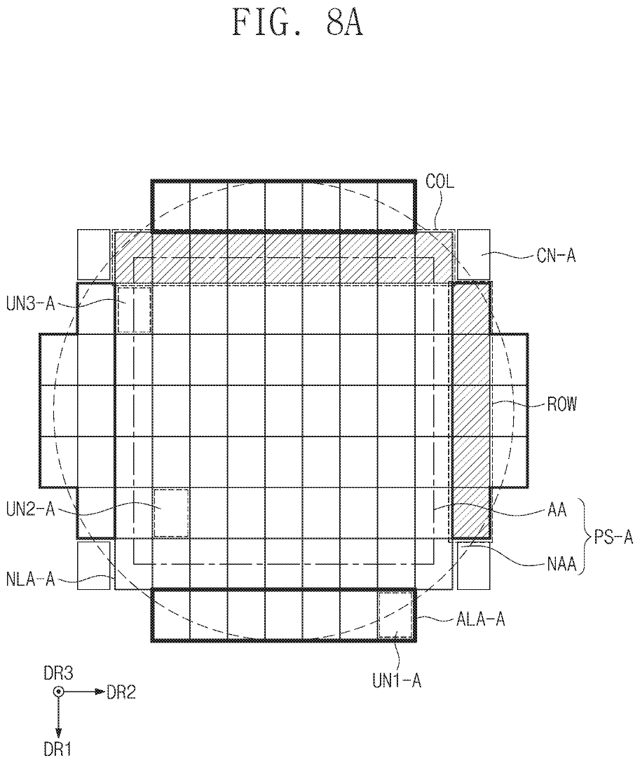

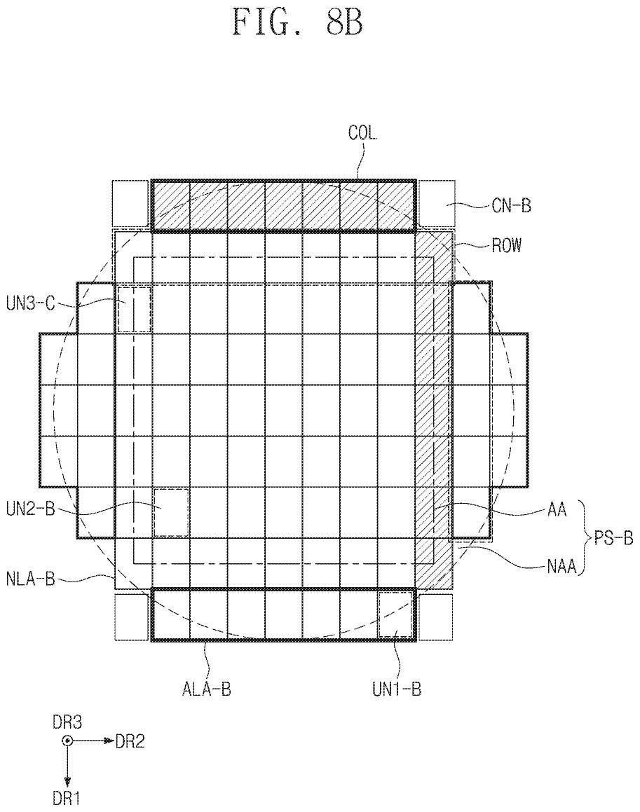

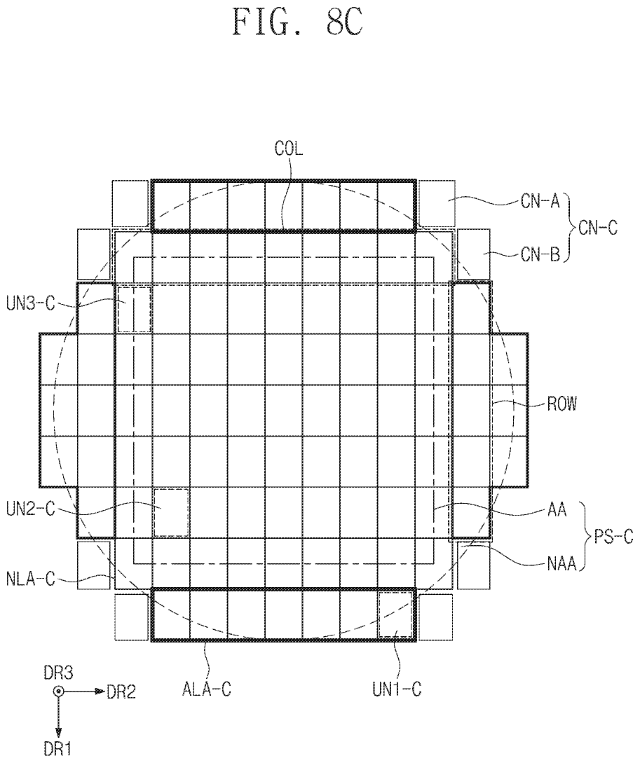

FIG. 7 is a plan view illustrating a nano-imprinting stamp according to an embodiment of the inventive concept. FIGS. 8A to 8C are plan views each illustrating a nano-imprinting stamp according to an embodiment of the inventive concept.

In FIGS. 7, 8A, 8B, and 8C, a solid line depicts a region on which a single exposure step described with reference to FIGS. 2A and 2B is performed. For convenience in illustration, the preliminary substrate PS described with reference to FIG. 6A is depicted by a dotted line.

Referring to FIG. 7, each of exposure regions depicted by the solid line may be a region to be patterned by the single exposure step. In an embodiment, before the fabrication of the nano-imprinting stamp, a camera module or the like may be used to virtually dividing the preliminary substrate PS into layouts to be patterned. Thus, each of the exposure regions overlapped with the preliminary substrate PS may be a region, on which some steps of the patterning process of FIGS. 6C to 6L will be performed. For example, steps of depositing, coating, or spraying the etch layer EL, the masking layers PR1, and PR2, or the etching gases ET1, ET2, and ET3 or an exposure step may be performed on each of the exposure regions.

In an embodiment, the preliminary substrate PS may include a first unit region UN1 defined within the peripheral region NAA, a second unit region UN2 defined within the active region AA, and a third unit region UN3 which is overlapped with both of the active region AA and the peripheral region NAA.

The first unit region UN1 may be a region on which the alignment pattern AP (e.g., see FIG. 2B) is formed. The first unit region UN1 may be a region on which the first patterning process described with reference to FIGS. 6C to 6G will be performed.

The second unit region UN2 may be a region on which the imprint pattern NP (e.g., see FIG. 2A) is formed. The second unit region UN2 may be a region on which the second patterning process described with reference to FIGS. 6H to 6L is performed.

The third unit region UN3 may be set to be overlapped with both of the active region AA and the peripheral region NAA. An additional pattern formed on the third unit region UN3 may have substantially the same structure as the imprint pattern NP (e.g., see FIG. 2A) formed on the second unit region UN2. In an embodiment, since the imprint pattern NP on the active region AA has substantially the same structure as the additional pattern formed on the third unit region UN3, it may be possible to prevent the imprint pattern NP from being abnormally formed in a border region between the active region AA and the peripheral region NAA.

As shown in FIG. 8A, a plurality of the third unit regions, which are arranged in the second direction DR2, may be defined as a column region COL. In addition, the first unit regions provided in the peripheral region NAA may be defined as a row region ROW. In an embodiment, the imprint pattern NP may include nanometer-sized patterns, which are formed by a patterning process, but uniformity of the nano-patterns may decrease with decreasing distance from the edge or corner of the active region AA.

To avoid these issues, an edge region CN-A may be added at an intersectional region between the column and row regions COL and ROW. The edge region CN-A may be defined to be overlapped with a portion of the preliminary substrate PS. The additional pattern formed on the edge region CN-A may have substantially the same structure as the imprint pattern NP (e.g., see FIG. 2A) on the second unit region UN2.

Unlike the structure shown in FIG. 8A, FIG. 8B illustrates an example in which a plurality of the first unit regions arranged in the second direction DR2 is defined as the column region COL and a plurality of the third unit regions arranged in the first direction DR1 is defined as the row region ROW. In an embodiment, an edge region CN-B may be defined at an intersectional region between the column region COL and the row region ROW.

FIG. 8C illustrates an example of a structure for which the embodiments of FIGS. 8A and 8B are applied. An area of the imprint pattern NP may be enlarged due to an increase in an edge region CN-C.

According to an embodiment of the inventive concept, the edge regions may be additionally provided near corners of the active region AA, it may be possible to improve uniformity of the nano-imprinting stamp WF.

FIGS. 9A to 9C are plan views each illustrating a usage example of a nano-imprinting stamp according to an embodiment of the inventive concept. For convenience in illustration, only four first sub-patterns SP-A located adjacent to corners of the active region AA are illustrated in FIG. 9A. In the following description, an element previously described with reference to 1 to 4A may be identified by the same reference number without repeating an overlapping description thereof.

The nano-imprinting stamp WF may be used for a nano imprint process. In an embodiment of the inventive concept, the nano-imprinting stamp WF may include the imprint pattern NP and the alignment pattern AP which are provided on the active region AA and the peripheral region NAA, respectively. In the nano imprint process, the nano-imprinting stamp WF may be used as a master mold for transcribing or copying the shapes of the imprint pattern NP-A and the first sub-patterns SP-A onto a target film FL.

As a result of the transcription process, the target film FL may include an imprint pattern NP-B and a first sub-pattern SP-B each of which has substantially the same shape of a corresponding pattern in the nano-imprinting stamp WF. The target film FL may be used to realize a polarizer of a display panel.

FIG. 9C illustrates a portion of a polarizer made of glass GL. The pattern-transcription process may be performed using a nano imprint process. For a polarizer for a large-area display panel, a nano-pattern corresponding to one active region may be formed by performing the transcription process repeatedly. In the case where the transcription process is performed repeatedly, the first sub-pattern SP-C may be used as an align mark for aligning a position of a nano-pattern to be transcribed in a next step, on the glass GL.

FIG. 9C illustrates a shape of an imprint pattern NP-C that is formed by transcribing a first active region AA1 and a second active region AA2 respectively. In an embodiment, the imprint pattern NP-C and the first sub-pattern SP-C, which are spaced apart from each other, are simultaneously formed on the glass GL, and thus, without an additional alignment step, the first sub-pattern SP-C may be used to align a plurality of nano-patterns with each other.

According to an embodiment of the inventive concept, an alignment pattern is provided to align nano-patterns with each other, and this may make it possible to improve uniformity of a nano-imprinting stamp. Furthermore, an alignment pattern is provided to prevent a misalignment issue in the nano imprint process. Accordingly, it may be possible to realize a nano-imprinting stamp with improved reliability.

While example embodiments of the inventive concept have been particularly shown and described, it will be understood by one of ordinary skill in the art that variations in form and detail may be made therein without departing from the spirit and scope of the attached claims.

What is claimed is:

1. A nano-imprinting stamp, comprising:
a base substrate;
an imprint pattern provided on the base substrate; and
an alignment pattern provided on the base substrate adjacent to the imprint pattern, the alignment pattern having a different shape from the imprint pattern,
wherein the base substrate comprises a groove region formed between the imprint pattern and the alignment pattern in which a top surface of the imprint pattern being lower than a bottom surface of the alignment pattern.

2. The nano-imprinting stamp of claim 1, wherein the base substrate includes an active region which has a rectangular planar shape and a peripheral region which is disposed adjacent to an edge of the active region,
the imprint pattern is provided on the active region, and
the groove region and the alignment pattern are provided on the peripheral region.

3. The nano-imprinting stamp of claim 2, further comprising an additional pattern provided between the groove region and the imprint pattern,
wherein the additional pattern has substantially a same shape as the imprint pattern.

4. The nano-imprinting stamp of claim 3, wherein, when measure in a specific direction, a sectional width of the imprint pattern ranges from 30 nm to 50 nm, and a sectional width of the alignment pattern ranges from 1 μm to 100 μm.

5. The nano-imprinting stamp of claim 1, wherein the imprint pattern comprises a plurality of nano-patterns, which extend in a predetermined direction and are spaced apart from each other in a direction crossing the predetermined direction, and
the nano-patterns are provided to have a pitch ranging from 90 nm to 100 nm.

6. The nano-imprinting stamp of claim 1, wherein the imprint pattern has a trapezoidal shape when viewed in a sectional view.

7. The nano-imprinting stamp of claim 1, wherein the base substrate has a circular shape, when viewed in a plan view.

8. A nano-imprinting stamp, comprising:
a base substrate including an active region and a peripheral region adjacent to the active region, the base substrate comprising a groove region which is provided in the peripheral region and is recessed from a top surface of the base substrate;
an imprint pattern provided on the active region;
an alignment pattern spaced apart from the imprint pattern, the alignment pattern; and
an additional pattern disposed on both of the active region and the peripheral region and provided between the imprint pattern and the alignment pattern,
wherein the additional pattern has substantially a same shape as the imprint pattern.

9. The nano-imprinting stamp of claim 8, wherein the groove region is provided between the additional pattern and the alignment pattern.

10. The nano-imprinting stamp of claim 9, wherein the alignment pattern has a mesh-shaped structure in which a plurality of openings are formed.

11. The nano-imprinting stamp of claim 9, wherein the alignment pattern has a stripe structure including a plurality of line patterns and a plurality of openings interposed between the line patterns.

12. The nano-imprinting stamp of claim 9, wherein the first sub-pattern has a mesh-shaped structure in which a plurality of openings are formed.

13. The nano-imprinting stamp of claim 8, wherein a thickness of the imprint pattern is substantially equal to a depth of the groove region.

14. A method of fabricating a nano-imprinting stamp, comprising:
providing a preliminary substrate including a base substrate and an etch layer disposed on the base substrate to fully cover the base substrate;
forming a blocking mask to cover a portion of the etch layer overlapped with an active region and to expose a portion of the etch layer overlapped with a peripheral region;
forming an alignment pattern by coating the preliminary substrate with a first masking layer and performing a first patterning process using a first mask;
removing a portion of the base substrate which is exposed by the blocking mask and the alignment pattern to form a groove region; and
forming an imprint pattern by coating the preliminary substrate with a second masking layer and performing a second patterning process using a second mask, the imprint pattern having a different shape from the alignment pattern,
wherein the first mask is formed to expose a portion of the first masking layer overlapped with the peripheral region, and
the second mask is formed to expose a portion of the second masking layer overlapped with the active region.

15. The method of claim 14, wherein the first patterning process further comprises hardening the exposed portion of the first masking layer, which is exposed by the first mask, to form a first photomask.

16. The method of claim 15, wherein the alignment pattern is formed by etching a region of the etch layer exposed by the first photomask.

17. The method of claim 14, wherein the second patterning process further comprises hardening the exposed portion of the second masking layer, which is exposed by the second mask, to form a second photomask.

18. The method of claim 17, wherein the imprint pattern is formed by etching a region of the etch layer exposed by the second photomask.

19. The method of claim 14, wherein the first patterning process comprises a plurality of first unit steps, each of which is performed to define a first unit region, on which the alignment pattern is formed,
the second patterning process comprises a plurality of second unit steps, each of which is performed to define a second unit region, on which the imprint pattern is formed,
the peripheral region is divided by a plurality of the first unit regions and the second unit region adjacent to the first unit region, and
the active region is divided by a plurality of the second unit regions.

20. The method of claim 19, further comprising an edge region overlapped with a portion of the peripheral region,
wherein one of the first unit steps is performed on the edge region to form the imprint pattern on the edge region.
